(19) United States
(12) Patent Application Publication
(10) Pub. No.: US 2002/0072132 A1
(43) Pub. Date: Jun. 13, 2002

(54) SEMICONDUCTOR INTEGRATED CIRCUIT

(76) Inventor: Noboru Sekiguchi, Tokyo (JP)

Correspondence Address: LEYDIG VOIT & MAYER, LTD, 700 THIRTEENTH ST. NW, SUITE 300, WASHINGTON, DC, 20005-3960, US

(21) Appl. No.: 09/841,002

(22) Filed: Apr. 25, 2001

(30) Foreign Application Priority Data
Dec. 8, 2000 (JP) 2000-374022

(51) Int. Cl. H01L 21/66

(52) U.S. Cl. 438/14

(57) ABSTRACT

If a packaged IC chip is judged to be defective during inspection just before its shipment, then, optimum correction information is calculated from the results of the electric characteristics of the IC chip. The calculated correction information is written in a nonvolatile memory for correction in the semiconductor chip to correct the electric characteristics of the semiconductor chip. The characteristics corrected IC chip is then inspected again.

### FIELD OF THE INVENTION

The present invention in general relates to a semiconductor integrated circuit and a process for manufacturing a semiconductor integrated circuit. More particularly, this invention relates to a semiconductor integrated circuit reduced in the occurrence of defectives when the electric properties are inspected in a manufacturing process and to a process for manufacturing a semiconductor integrated circuit.

### BACKGROUND OF THE INVENTION

FIG. 8 is a flowchart showing a process for manufacturing a conventional semiconductor integrated circuit (hereinafter referred to as IC). In FIG. 8, the process of manufacturing an IC is carried out by a combination of a filming step of forming thin films of various materials on a silicon wafer (Step S101), a lithographic step of processing these thin films into a fixed shape by performing patterning and etching on these thin films (Step S102) and an impurity introduction step of adding minute conductive impurities to silicon (Step S103). The process involving these three steps is called a diffusion step by which an IC having transistors, resistors and capacitors integrated on a silicon wafer is fabricated.

The wafer into which the IC is incorporated by the diffusion step is then subjected to a G/W check step (Step S200). Here, G/W is an abbreviation for Good chip/Wafer. In the G/W check step, whether every IC chip on the wafer obtained in the diffusion step is good or inferior is determined.

The G/W check step will be briefly explained herein below. In the G/W check step, first the wafer is set on a measuring stage. Using the so-called probe card in which probes are disposed in advance in accordance with the positions of all electrode pads of ICs, each probe is brought into contact with the electrode pad of each IC. Signal lines corresponding to all probes are delivered from the probe card and connected to a tester.

In the condition, the tester outputs an input signal waveform which is programmed in advance through the input electrode pad of the IC. The tester also reads a fixed signal waveform output from the output terminal of the IC corresponding to the above input signal and determines whether the IC is good or inferior on the basis of the read result. Here, ICs which are judged to be inferior (Step S200NG) are treated as defectives and only ICs which are judged to be good (Step S200) are subjects to be treated in the subsequent steps.

After the G/W check step is finished, the wafer completed by incorporating as to a circuit pattern in the diffusion step is subjected to a dicing step of cutting the wafer into individual chips (Step S301). At this time, the chip which is judged to be inferior in the G/W check step is taken away as a matter of course.

The cut good products are then placed on and applied to an island of a lead frame in a mount step (Step S302) and an electrode pad on the IC chip is electrically connected to a lead of the lead frame by using a gold wire in a bonding step (Step S303).

In succession, the lead frame mounted with the IC chip is set in a mold and the whole chip is wrapped by forcedly feeding a resin fluidized at an elevated temperature in a sealing step (Step S304). Then, the IC is cut off from the lead frame and the lead is shaped. After the lead wire is soldered, a trademark, a name of an article and a lot number are printed on the surface of the IC mold by using a laser to finish packaging in a finishing step (Step S305). Here, a series of steps comprising the aforementioned dicing step, mount step, bonding step, sealing step and finishing step is referred to as an assembling and finishing step.

The packaged IC is subjected to a screening inspection step of undergoing inspections for qualities which are not exactly measured in the state of the wafer treated in the G/W check step and for qualities which are more strict in the light of the product specification. This step also involves characteristic tests concerning the function and performance of the IC, inspections of the shape and size of the lead and printed condition, other outward appearance and a reliability test. Only ICs which are judged to be good are shipped (Step S4000K) and ICs which are judged to be inferior are treated as defectives and disposed (Step S400NG).

The process of manufacturing the IC is roughly divided into two steps represented by a wafer process involving the above diffusion step and G/W check step and an assembly process involving the above assembling and finishing step and screening and inspection step.

As outlined above, in the process of manufacturing the IC, the electric characteristics of resistances, capacitors and transistors which constitute the IC and the characteristics such as timing between signals inside of the circuit are determined by the fabrication of the IC in the diffusion step. Therefore, disorders or dispersions produced in the diffusion step are directly reflected on the characteristics of the IC and ICs which are judged to be defectives in the G/W check step or the screening inspection step cannot be corrected as good chips.

For this, an IC is proposed in which a nonvolatile memory such as a flash memory is disposed therein, the results of electric characteristics measured when the IC is shipped are written in a nonvolatile memory and the circuit characteristics can be trimmed based on the data written in the nonvolatile memory when the circuit is operated.

However, such an IC which can be trimmed based on the data of the nonvolatile memory as proposed above has a purpose of trimming to cancel dispersions between ICs for ICs to be shipped, namely, ICs determined as good products in the G/W check step and the screening inspection step. This proposal, therefore, has the problem that it does not present a large cause leading to the result that the generation of defectives is reduced, that is, the yield is improved.

Particularly, much progress has recently been made in regard to large-scale and fine LSIs. This makes it difficult to regulate the electric characteristics and timing of signals. Therefore, it is hard to cancel the dispersions of ICs by trimming after these ICs are shipped. There is much need of reducing defectives in the manufacturing process.

### SUMMARY OF THE INVENTION

It is an object of this invention to providing a semiconductor integrated circuit which ensures that the electric characteristics of ICs can be improved, the yield can be improved and the dispersions of the characteristics as products can be reduced by correcting the electric characteristics in a manufacturing process on the basis of test results in a G/W check step and a screening inspection step and also providing a process of manufacturing a semiconductor integrated circuit.

The semiconductor integrated circuit according to one aspect of this invention comprises a nonvolatile memory for storing correction information of electric characteristics, the information allowing a semiconductor chip to be determined as a good product in the case where the semiconductor chip is judged to be a defective based on the result of inspection of the electric characteristics in a manufacturing process, an external terminal for writing the correction information in the nonvolatile memory and an element block which is the subject to be inspected for the electric characteristics and of which the characteristic value is determined in the manufacturing process on the basis of the correction information stored in the nonvolatile memory.

According to the above-mentioned aspect, when a semiconductor chip is judged to be a defective, correction information which is calculated from the results of the electric characteristics of the semiconductor chip and allows the semiconductor chip to be determined as a good product is stored in the nonvolatile memory and the electric characteristics of the element block is corrected based on the stored correction information and therefore even a semiconductor integrated circuit which is once judged to be a defective is treated as a good product in other manufacturing steps.

Furthermore, in the semiconductor integrated circuit, the external terminal is placed at a position where it is sealed by packaging.

Thus, when the writing of the correction information is finished before the semiconductor chip is packaged, the external terminal for writing is useless and therefore a lead which is swept from the external terminal to the outside of the package is useless by placing the external terminal at a position where it is sealed by packaging.

Furthermore, in the semiconductor integrated circuit, the element block is a resistance variable block in which two or more combinations of a transistor that is on/off controlled by the correction information and a resistor connected in series to the transistor are connected to each other in parallel.

Thus, the resistance of the resistor which affects the electric characteristics can be corrected based on the correction information stored in the nonvolatile memory.

Furthermore, in the semiconductor integrated circuit, the element block is a capacitance variable block in which two or more combinations of a transistor that is on/off controlled by the correction information and a capacitor connected in series to the transistor are connected to each other in parallel.

Thus, the capacitance of the capacitor which affects the electric characteristics can be corrected based on the correction information stored in the nonvolatile memory.

Furthermore, in the semiconductor integrated circuit, the element block is a delay variable block in which two or more delay units that are inserted into or removed from a signal path by the correction information are connected to each other in series.

Thus, the delay which determines signal timing among the electric characteristics can be corrected based on the correction information stored in the nonvolatile memory.

The process for manufacturing a semiconductor integrated circuit according to another aspect of this invention comprises a wafer process involving a diffusion step of fabricating semiconductor chips on a semiconductor wafer and a first inspection step for the semiconductor chip and an assembly process involving an assembling and finishing step of cutting out a semiconductor chip from the semiconductor wafer and packaging the semiconductor chip and a second inspection step for the packaged semiconductor chip. The second inspection step involves steps of inspecting the electric characteristics of the packaged semiconductor chip, calculating correction information of electric characteristics, the information allowing the semiconductor chip to be determined as a good product when the semiconductor chip is judged to be a defective on the basis of the results of the electric characteristics, writing the calculated correction information in the nonvolatile memory of the semiconductor chip and performing the second inspection step recursively to inspect the semiconductor chip whose electric characteristics are corrected based on the written correction information.

According to the above-mentioned aspect, since optimum correction information is calculated from the results of the electric characteristics of a packaged semiconductor chip just before the shipment and the calculated correction information is written in the nonvolatile memory for correction in the semiconductor chip to correct the electric characteristics of the semiconductor chip, the electric characteristics can be corrected in the manufacturing process.

The process for manufacturing a semiconductor integrated circuit according to still another aspect of this invention comprises a wafer process involving a diffusion step of fabricating semiconductor chips on a semiconductor wafer and a first inspection step for the semiconductor chip and an assembly process involving an assembling and finishing step of cutting out a semiconductor chip from the semiconductor wafer and packaging the semiconductor chip and a second inspection step for the packaged semiconductor chip. The first inspection step involves steps of inspecting the electric characteristics of the semiconductor chip, calculating correction information of electric characteristics, the information allowing the semiconductor chip to be determined as a good product when the semiconductor chip is judged to be a defective on the basis of the results of the electric characteristics, writing the calculated correction information in the nonvolatile memory of the semiconductor chip and performing the first inspection step recursively to inspect the semiconductor chip whose electric characteristics are corrected based on the written correction information.

According to the above-mentioned aspect, since optimum correction information is calculated from the results of the inspection of the electric characteristics of a semiconductor chip put in the condition that it is disposed on a wafer and the calculated correction information is written in the nonvolatile memory for correction in the semiconductor chip to correct the electric characteristics of the semiconductor chip, the electric characteristics can be corrected in the manufacturing process and the necessity of taking out the external terminal used for writing of the correction information is obviated in the packaged semiconductor chip.

Other objects and features of this invention will become apparent from the following description with reference to the accompanying drawings.

### BRIEF DESCRIPTION OF THE DRAWINGS

FIG. 1 is a flowchart showing a process for manufacturing a semiconductor integrated circuit according to a first embodiment;

FIG. 2 is a flowchart showing a process for manufacturing a semiconductor integrated circuit according to a second embodiment;

FIG. 3 is a view showing the condition that a semiconductor integrated circuit according to a second embodiment is disposed on a wafer;

FIG. 4 is a view showing the condition that a semiconductor integrated circuit according to a second embodiment is packaged;

FIG. 5 is a circuit diagram showing a part of a semiconductor integrated circuit according to a third embodiment;

FIG. 6 is a circuit diagram showing a part of a semiconductor integrated circuit according to a fourth embodiment;

FIG. 7A and FIG. 7B are circuit diagrams showing a part of a semiconductor integrated circuit according to a fifth embodiment; and

FIG. 8 is a flowchart showing a process for manufacturing a conventional semiconductor integrated circuit.

### DESCRIPTION OF THE PREFERRED EMBODIMENTS

Preferred embodiments of a semiconductor integrated circuit and a process for manufacturing a semiconductor integrated circuit according to the present invention will be hereinafter explained in detail with reference to the drawings. These embodiments, however, are not intended to be limiting of the present invention.

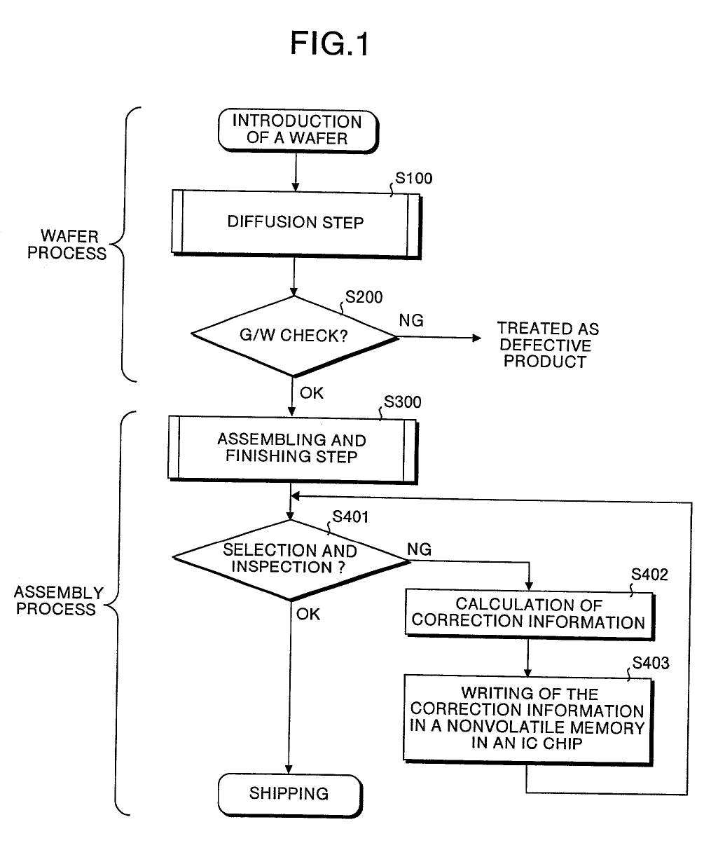

First, a semiconductor integrated circuit and a process for manufacturing a semiconductor integrated circuit according to a first embodiment will be explained. FIG. 1 is a flowchart showing the process for manufacturing a semiconductor integrated circuit (hereinafter referred to as IC) according to the first embodiment. This flowchart shows a process for manufacturing a semiconductor integrated circuit according to a first embodiment in particular.

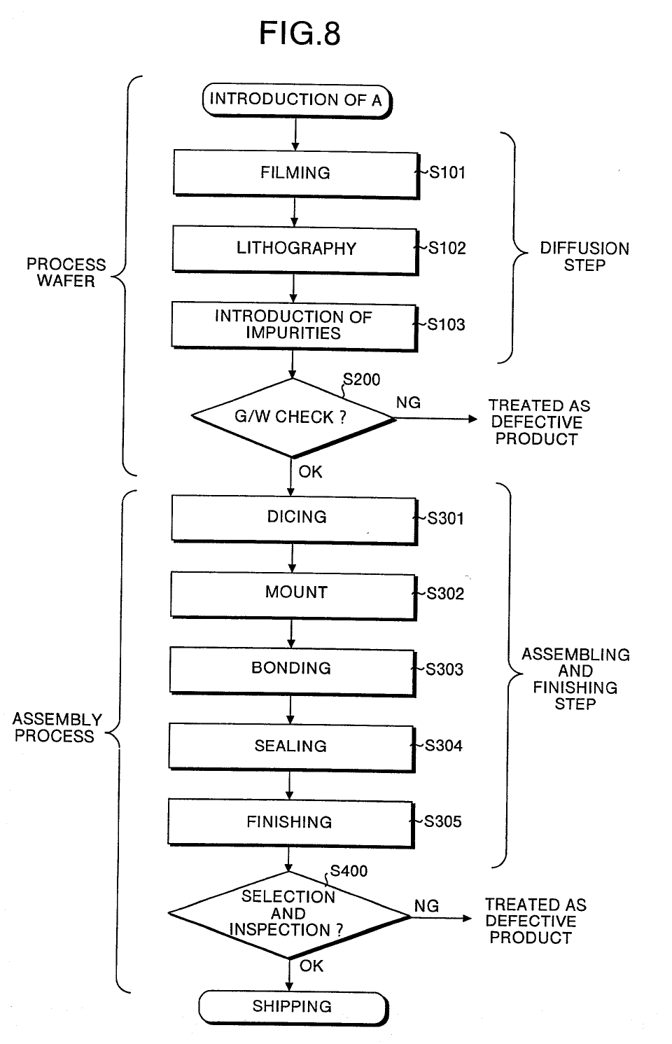

In FIG. 1, a diffusion step (Step S100) shows a series of steps including a filming step, a lithographic step and an impurity introduction step (Steps S101 to S103) as shown in FIG. 8 and the G/W check step (Step S200) is the same as the G/W check step shown in FIG. 8 and therefore explanations of these steps are omitted here. Also, the assembling and finishing step (Step S300) shows a series of steps consisting of the dicing step, mount step, bonding step, sealing step and finishing step (Steps S301 to S305) shown in FIG. 8 and therefore explanations of this step is omitted.

It is to be noted that ICs to be produced here are considered to be provided with a nonvolatile memory for storing correction information explained later and an external terminal used to write the correction information in the nonvolatile memory.

The manufacturing process shown in FIG. 1 is different from a conventional IC manufacturing process in the treatments subsequent to the screening inspection step. In the screening inspection step shown in FIG. 1, a tester is first used to examine an IC packaged in an assembling and finishing step for qualities which are not exactly measured in the state of the wafer treated in the G/W check step and for qualities which are more strict in the light of the product specification as usual. At this time, with regard to an IC which is judged to be a defective (Step S401NG), the tester calculates, as correction information, difference values of electric characteristics required for the IC to be determined as a good product (Step S402).

Then, the calculated correction information is written in the nonvolatile memory through the aforementioned external terminal by the tester (Step S403). The IC is provided with an element portion, which is a subject to be inspected, as an element block whose characteristics are variable corresponding to a predetermined signal and the characteristics of the element block are set according to a signal shown by the above correction information.

The IC in the condition as corrected by the correction information in this manner is again inspected as it is in the screening inspection step. If the IC is judged to be a good product as a result of the inspection, it is certified as an IC fulfilling the prescribed requirements for the electric characteristics and the IC is then subjected to tests concerning the shape and size of a lead, printing conditions, other outward appearance and reliability. If the IC is finally judged to be a good product, it is shipped as a good IC.

As is explained above, the semiconductor integrated circuit and process for manufacturing the semiconductor integrated circuit according to the first embodiment ensures that since optimum correction information is calculated from the results of the electric characteristics of a packaged semiconductor chip just before the shipment and the calculated correction information is written in the nonvolatile memory for correction in the IC to correct the electric characteristics of the IC, the electric characteristics can be corrected in the manufacturing process, the electric characteristics can be improved, the yield can be improved and production dispersion can be restrained. Also, since the corrected IC is again subjected to a screening and inspection step in the manufacturing process, a defective resulting from a mistake in correction is prevented from shipping.

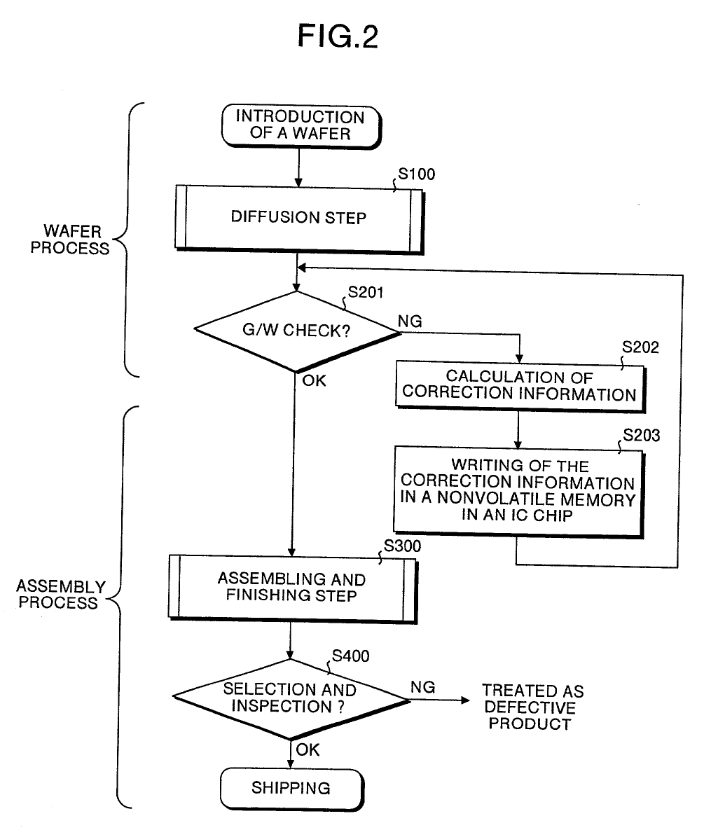

Next, a semiconductor integrated circuit and a process for manufacturing a semiconductor integrated circuit according to a second embodiment will be explained. FIG. 2 is a flowchart showing the process for manufacturing a semiconductor integrated circuit (hereinafter referred to as IC) according to the second embodiment. This flowchart shows a process for manufacturing a semiconductor integrated circuit according to a second embodiment in particular.

In FIG. 2, a diffusion step (Step S100) shows a series of steps including a filming step, a lithography step and an impurity introduction step (Steps S101 to S103) as shown in FIG. 8 and therefore explanations of this step is omitted. Also, because the assembling and finishing step (Step S300) shows a series of steps consisting of the dicing step, mount step, bonding step, sealing step and finishing step (Steps S301 to S305) shown in FIG. 8 and the screening selection step (Step S400) is the same as the assembling and finishing step shown in FIG. 8, the explanations of these steps are omitted.

It is to be noted that in the same manner as in the first embodiment, ICs to be produced here are considered to be provided with a nonvolatile memory for storing correction information explained later and an external terminal used to write the correction information in the nonvolatile memory.

The manufacturing process shown in FIG. 2 is different from a conventional IC manufacturing process in treatment in the G/W check step. In the G/W check step shown in FIG. 2, a tester is first used to examine a wafer, into which ICs are incorporated in the diffusing step, for electric characteristics by the G/W check step as usual (Step S201). At this time, with regard to an IC which is judged to be a defective, the tester calculates, as correction information, difference values of electric characteristics required for the IC to be determined as a good product (Step S202).

Then, the calculated correction information is written in the nonvolatile memory through the aforementioned external terminal by the tester (Step S203). The IC is provided with an element portion, which is a subject to be inspected, as an element block whose characteristics are variable corresponding to a predetermined signal and the characteristics of the element block are set according to a signal shown by the above correction information.

The IC in the condition as corrected by the correction information in this manner is again inspected as it is in the G/W check step. If the IC is judged to be a good product as a result of the inspection, it is certified as an IC fulfilling the prescribed requirements for the electric characteristics and the IC is then subjected to treatments subsequent to and including the assembling and finishing step.

As outlined above, the correction information is written in the packaged IC in the first embodiment whereas the correction information is written in an IC put in an uncovered condition on the wafer. In the second embodiment, it is unnecessary that the external terminal required to write the correction information is always formed as an electrode pad to be connected to a lead frame.

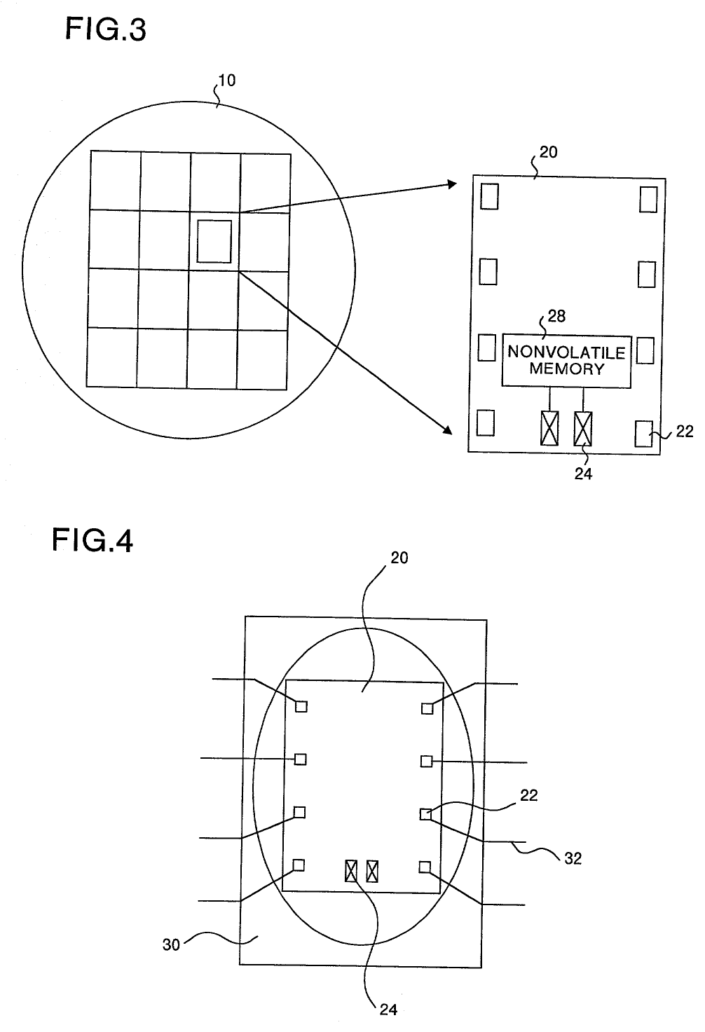

FIG. 3 is a view showing the condition that the semiconductor integrated circuit according to a second embodiment is disposed on a wafer. As shown in FIG. 3, an IC 20 in the condition that it is placed on a wafer 10 is provided with an external terminal 24 used to write the correction information in a nonvolatile memory 28 in addition to an electrode pad 22 used to connect the IC 20 to the lead frame. The position of the external terminal 24 is not restricted by the position relative to lead frames such as other electrode pads 22.

FIG. 4 is a view showing the condition that the semiconductor integrated circuit according to the second embodiment is packaged. As shown in FIG. 4, in a packaged IC 30, an external terminal 24 for writing in a nonvolatile memory 28 may be in a sealed condition though a lead 32 is connected to an electrode pad 22.

As is explained above, according to the semiconductor integrated circuit and process for manufacturing the semiconductor integrated circuit according to the second embodiment, optimum correction information is calculated from the results of the electric characteristics of an IC put in the condition that it is disposed on a wafer and the calculated correction information is written in the nonvolatile memory for correction in the IC to varies the electric characteristics of the IC. Therefore, in addition to the effects of the first embodiment, all pins of the leads connected to the electrode pads may be used for purposes other than writing in the nonvolatile memory because the external terminal used to write the correction information is not exposed. Also, since the corrected IC is again subjected to the G/W check step in the manufacturing process, defectives resulting from a mistake in correction is prevented from feeding to the assembly process.

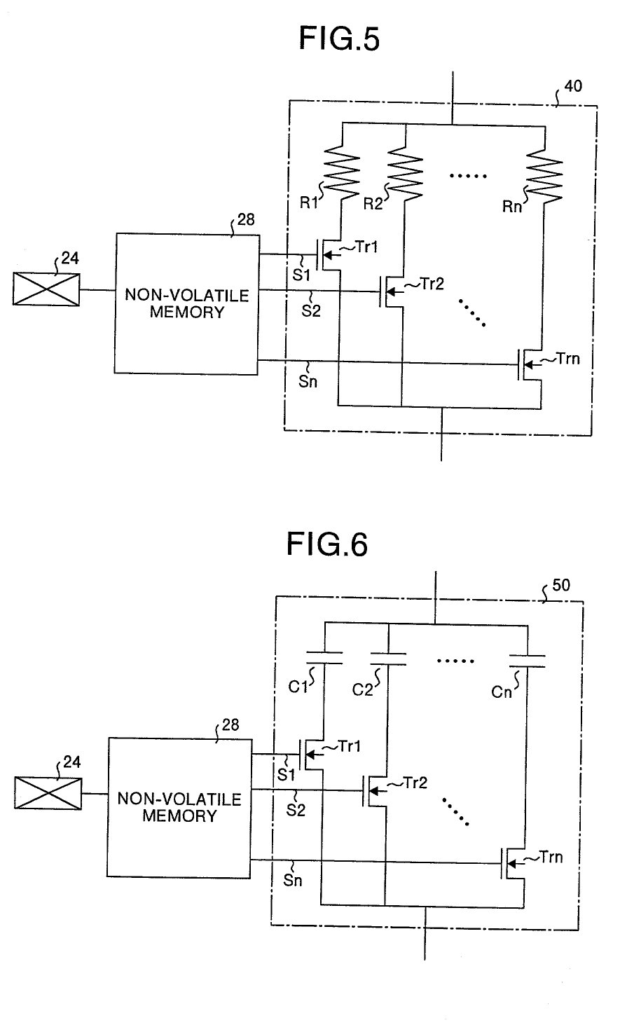

Next, a semiconductor integrated circuit according to a third embodiment will be explained. The semiconductor integrated circuit according to the third embodiment shows a specific example of the semiconductor integrated circuit according to the first embodiment or 2. FIG. 5 is a flowchart showing a part of the semiconductor integrated circuit according to the third embodiment.

In FIG. 5, numerical character 28 represents a nonvolatile memory storing the correction information explained in the first embodiment or 2, numerical character 24 represents an external terminal used to write the correction information in the nonvolatile memory 28 and numerical character 40 represents an element block whose characteristics are variable corresponding to a prescribed signal. Here, particularly the element block 40 is variable in resistance.

The element block 40 has n structural components in which a resistor element R1 and a transistor Tr1 are connected to each other in series and which are arranged in parallel. Each of the resistors R1 to Rn is effected by placing transistors Tr1 to Trn corresponding to each resistor in an ON condition. Further, a signal output from the nonvolatile memory 28 is input to a gate of each of these transistors Tr1 to Trn. Namely, each of these resistors R1 to Rn in the element block 40 is determined as to whether it is effective or ineffective on the basis of the correction information stored in the nonvolatile memory 28.

For instance, the resistances of the resistors R1 to Rn are represented by r1 to rn respectively and signals input to the gates of the transistors Tr1 to Trn are represented by S1 to Sn respectively. Here, each of these signals S1 to Sn makes a corresponding transistor off when it is “0” and on when it is “1”.

Therefore, when the resistance of the entire element block is R, the following relation is established between R, the resistances r1 to rn and the signals S1 to Sn.

1/R=Σ(1/ri×Si) [i=1 to n]

It is found from this equation that the resistance R of the element block can be made variable by the correction information stored in the nonvolatile memory 28.

As is explained above, the semiconductor integrated circuit according to the third embodiment ensures that the resistance can be corrected in the IC manufacturing process since the resistor element section which is a subject of the G/W check step and screening inspection step is provided as an element block which varies in resistance corresponding to a predetermined signal and the resistance of the element block varies corresponding to the correction information of the nonvolatile memory 28.

Next, a semiconductor integrated circuit according to a fourth embodiment will be explained. The semiconductor integrated circuit according to the fourth embodiment shows a specific example of the semiconductor integrated circuit according to the first embodiment or 2. FIG. 6 is a flowchart showing a part of the semiconductor integrated circuit according to the fourth embodiment.

In FIG. 6, numerical character 28 represents a nonvolatile memory storing the correction information explained in the first embodiment or 2, numerical character 24 represents an external terminal used to write the correction information in the nonvolatile memory 28 and numerical character 50 represents an element block whose characteristics are variable corresponding to a prescribed signal as explained in the first embodiment or 2. Here, particularly the element block 50 is variable in capacitance.

The element block 50 has n structural components in which a capacitor C1 and a transistor Tr1 are connected to each other in series and which are arranged in parallel. Each of the capacitors C1 to Cn is effected by placing transistors Tr1 to Trn corresponding to each capacitor in an ON condition. Further, a signal output from the nonvolatile memory 28 is input to a gate of each of these transistors Tr1 to Trn. Namely, each of these capacitors C1 to Cn in the element block 50 is determined as to whether it is effective or ineffective on the basis of the correction information stored in the nonvolatile memory 28.

For instance, the capacitances of the capacitors C1 to Cn are represented by c1 to cn respectively and signals input to the gates of the transistors Tr1 to Trn are represented by S1 to Sn respectively. Here, each of these signals S1 to Sn makes a corresponding transistor off when it is “0” and on when it is “1”.

Therefore, when the capacitance of the entire element block is C, the following relation is established between C, the capacitances c1 to cn and the signals S1 to Sn.

C=Σ(ci×Si) [i=1 to n]

It is found from this equation that the capacitance C of the element block can be made variable by the correction information stored in the nonvolatile memory 28.

As is explained above, the semiconductor integrated circuit according to the fourth embodiment ensures that the capacitance can be corrected in the IC manufacturing process since the capacitor element section which is a subject of the G/W check step and screening inspection step is provided as an element block which varies in capacitance corresponding to a predetermined signal and the capacitance of the element block varies corresponding to the correction information of the nonvolatile memory 28.

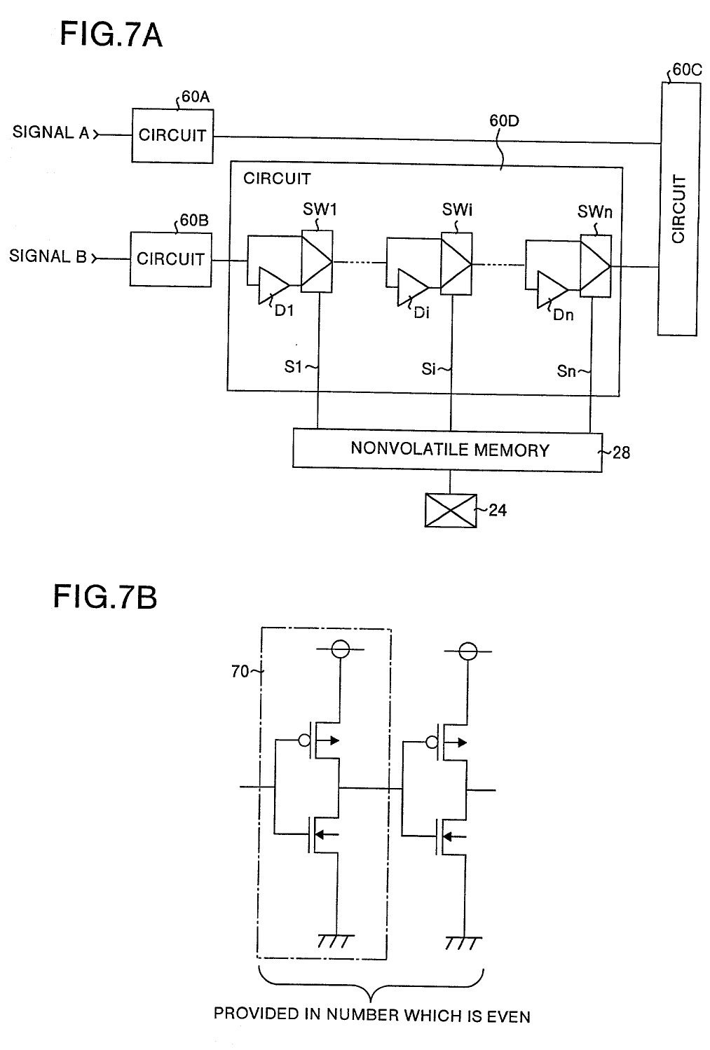

Next, a semiconductor integrated circuit according to a fifth embodiment will be explained. The semiconductor integrated circuit according to the fifth embodiment shows a specific example of the semiconductor integrated circuit according to the first embodiment or 2. FIG. 7A and FIG. 7B are circuit diagrams showing a part of the semiconductor integrated circuit according to the fifth embodiment.

In FIG. 7A, numerical character 28 represents a nonvolatile memory storing the correction information explained in the first embodiment or 2, numerical character 24 represents an external terminal used to write the correction information in the nonvolatile memory 28 and numerical character 60A to 60D represent a circuit block and. Particularly, the circuit 70, shown in FIG. 7B, is an element block whose characteristics are variable corresponding to a prescribed signal as explained in the first embodiment or 2. Here, a delay is made variable.

The circuit 60A is a circuit which accepts a signal A as the input, carry out the predetermined treatment of the signal A and then outputs the treated signal as the input to the circuit 60C. The circuit 60B is a circuit which accepts a signal B as the input, processes the signal B according to a predetermined method and then outputs the treated signal as the input to the circuit 60D. Also, the circuit 60D is, as shown in FIG. 7A, provided with n groups consisting of a buffer D1 which produces a delay of Δt and a selector SW1 which makes a selection as to whether the input signal is made to bypass or take a root via the aforementioned buffer D1 in series. In each of the selectors SW1 to SWn, the selection is made by switching corresponding to a signal output from the nonvolatile memory. Specifically, the signal input to the circuit 60D is delayed though a buffer selected based on the correction information stored in the nonvolatile memory.

The internal circuit of each of the buffers D1 to Dn, as shown in FIG. 7B, has a structure in which even-numbered inverters consisting of a p-type MOS transistor and an n-type MOS transistor which are complementarily connected to each other.

For instance, the respective delays of the buffers D1 to Dn are represented by Δt1 to Δt2 respectively and control signals input to the selectors SW1 to SWn are represented by S1 to Sn respectively. Here, each of these signals S1 to Sn switches a corresponding selector to select the bypassing root when it is “0” and to select the buffer root when it is “1”.

Therefore, when the delay of the entire circuit 60D is ΔT, the following relation is established between ΔT, the delays Δt1 to Δtn and the signals S1 to Sn.

ΔT=Σ(Δti×Si) [i=1 to n]

It is found from this equation that the delay ΔT of the circuit 60D can be made variable by the correction information stored in the nonvolatile memory 28.

As is explained above, the semiconductor integrated circuit according to the fifth embodiment ensures that the delay can be corrected and timing of the signal can be controlled in the IC manufacturing process since the delay element section which is a subject of the G/W check step and screening inspection step is provided as an element block which varies in delay corresponding to a predetermined signal and the delay of the element block varies corresponding to the correction information of the nonvolatile memory 28.

The present invention ensures that when a semiconductor chip is judged to be a defective in a manufacturing step, correction information which is calculated from the results of the electric characteristics of the semiconductor chip and allows the semiconductor chip to be determined as a good product is stored in the nonvolatile memory and the electric characteristics of the element block is corrected based on the stored correction information and therefore even a semiconductor integrated circuit which is once judged to be a defective is treated as a good product in other manufacturing steps, so that the invention produces the effect of bettering the electric characteristics, improving the yield and restraining the dispersion of manufacturing.

Furthermore, the present invention ensures that when the writing of the correction information is finished before the semiconductor chip is packaged, the external terminal for writing is useless and therefore a lead which is swept from the external terminal to the outside of the package is useless by placing the external terminal at a position where it is sealed by packaging, so that the invention produces the effect of being capable of limiting a restriction to the position of the external terminal.

Furthermore, the present invention ensures that the resistance of the resistor which affects the electric characteristics can be corrected based on the correction information stored in the nonvolatile memory, so that the invention produces the effect of bettering the electric characteristics, improving the yield and restraining the dispersion of manufacturing.

Furthermore, the present invention ensures that the capacitance of the capacitor which affects the electric characteristics can be corrected based on the correction information stored in the nonvolatile memory, so that the invention produces the effect of bettering the electric characteristics, improving the yield and restraining the dispersion of manufacturing.

Furthermore, the present invention ensures that the delay which determines signal timing among the electric characteristics can be corrected based on the correction information stored in the nonvolatile memory, so that the invention produces the effect of bettering the electric characteristics, improving the yield and restraining the dispersion of manufacturing.

Furthermore, the present invention ensures that since optimum correction information is calculated from the results of the electric characteristics of a packaged semiconductor chip just before the shipment and the calculated correction information is written in the nonvolatile memory for correction in the semiconductor chip to correct the electric characteristics of the semiconductor chip, the electric characteristics can be corrected in the manufacturing process and also the same inspection step is performed recursively for the corrected semiconductor chip, so that the invention produces the effect of preventing the shipment of defectives caused by a mistake of the correction.

Furthermore, the present invention ensures that since optimum correction information is calculated from the results of the inspection of the electric characteristics of a semiconductor chip placed in the condition that it is disposed on a wafer and the calculated correction information is written in the nonvolatile memory for correction in the semiconductor chip to correct the electric characteristics of the semiconductor chip, the electric characteristics can be corrected in the manufacturing process and the necessity of taking out the external terminal used for writing of the correction information is obviated in the packaged semiconductor chip and also the same inspection step is performed recursively for the corrected semiconductor chip, so that the invention produces the effect of preventing defectives caused by a mistake of the correction from being fed to the subsequent step.

Although the invention has been described with respect to a specific embodiment for a complete and clear disclosure, the appended claims are not to be thus limited but are to be construed as embodying all modifications and alternative constructions that may occur to one skilled in the art which fairly fall within the basic teaching herein set forth.

What is claimed is:

1. A semiconductor integrated circuit comprising:
a nonvolatile memory for storing correction information of electric characteristics, the information allowing a semiconductor chip to be determined as a good product in the case where the semiconductor chip is judged to be a defective based on the result of inspection of the electric characteristics in a manufacturing process;
an external terminal for writing the correction information in said nonvolatile memory; and
an element block which is the subject to be inspected for the electric characteristics and of which the characteristic value is determined in the manufacturing process on the basis of the correction information stored in said nonvolatile memory.

2. The semiconductor integrated circuit according to claim 1, wherein said external terminal is placed at a position where it is sealed by packaging.

3. The semiconductor integrated circuit according to claim 1, wherein said element block is a resistance variable block in which two or more groups of a transistor that is on/off controlled by the correction information and a resistor connected in series to the transistor are connected to each other in parallel.

4. The semiconductor integrated circuit according to claim 1, wherein said element block is a capacitance variable block in which two or more groups of a transistor that is on/off controlled by the correction information and a capacitor connected in series to the transistor are connected to each other in parallel.

5. The semiconductor integrated circuit according to claim 1, wherein said element block is a delay variable block in which two or more delay units that are inserted into or removed from a signal path by the correction information are connected to each other in series.

6. A process for manufacturing a semiconductor integrated circuit, the process comprising:
a wafer process involving,
a diffusion step of fabricating semiconductor chips on a semiconductor wafer; and
a first inspection step for the semiconductor chip; and
an assembly process involving,
an assembling and finishing step of cutting out a semiconductor chip from said semiconductor wafer and packaging the semiconductor chip; and
a second inspection step for the packaged semiconductor chip,
wherein said second inspection step involves steps of,
inspecting the electric characteristics of said packaged semiconductor chip,
calculating correction information of electric characteristics, the information allowing the semiconductor chip to be determined as a good product when the semiconductor chip is judged to be a defective on the basis of the results of the electric characteristics,
writing the calculated correction information in the nonvolatile memory of the semiconductor chip and performing the second inspection step recursively to inspect the semiconductor chip whose electric characteristics are corrected based on the written correction information.

7. A process for manufacturing a semiconductor integrated circuit, the process comprising:
a wafer process involving,
a diffusion step of fabricating semiconductor chips on a semiconductor wafer; and
a first inspection step for the semiconductor chip; and
an assembly process involving,
an assembling and finishing step of cutting out a semiconductor chip from said semiconductor wafer and packaging the semiconductor chip; and
a second inspection step for the packaged semiconductor chip,
wherein said first inspection step involves steps of,
inspecting the electric characteristics of said semiconductor chip,
calculating correction information of electric characteristics, the information allowing the semiconductor chip to be determined as a good product when the semiconductor chip is judged to be a defective on the basis of the results of the electric characteristics,
writing the calculated correction information in the nonvolatile memory of said semiconductor chip and performing the first inspection step recursively to inspect the semiconductor chip whose electric characteristics are corrected based on the written correction information.
